(19) United States
(12) Patent Application Publication
(10) Pub. No.: US 2022/0033425 A1
(43) Pub. Date: Feb. 3, 2022

(54) METAL ORGANIC FRAMEWORKS AND METHODS OF PREPARATION THEREOF

(71) Applicant: Royal Melbourne Institute of Technology, Melbourne (AU)

(72) Inventors: Heba Adel Aly ElSayed ElSayed AHMED, Oak Park (AU); Amgad Rezk Noshi Rezk, Bayswater (AU); Joseph J. RICHARDSON, St. Petersburg, FL (US); Leslie Yu-Ming YEO, Malvern East (AU)

(21) Appl. No.: 17/501,742

(22) Filed: Oct. 14, 2021

Related U.S. Application Data
(63) Continuation of application No. PCT/AU2020/050372, filed on Apr. 15, 2020.

(30) Foreign Application Priority Data
Apr. 15, 2019 (AU) 2019901294

(51) Int. Cl. C07F 15/02; C07F 1/08; B01J 20/22; C01B 37/00; B01J 19/00; B01L 3/00

(52) U.S. Cl. CPC C07F 15/025; C07F 1/08; B01J 20/226; C01B 37/00; B01L 2400/0439; B01L 3/50273; B01J 2219/00932; B01L 2400/0436; B01J 19/0093

(57) ABSTRACT

A method of preparing a Metal Organic Framework (MOF) with an acoustically-driven microfluidic platform, the method comprising: depositing a liquid comprising MOF precursors on a piezoelectric substrate of an acoustic microfluidic platform, the MOF precursors comprising a metal ion and an organic ligand, applying acoustic irradiation to the liquid to induce azimuthal liquid recirculation, which causes formation of the MOF within the liquid, and isolating the MOF.

### CROSS-REFERENCE TO RELATED APPLICATIONS

This application is a continuation of International Application No. PCT/AU2020/050372, filed on Apr. 15, 2020, which claims priority to Australian Patent Application No. 2019901294, filed on Apr. 15, 2019, each of which is incorporated by reference herein in its entirety.

### FIELD OF THE INVENTION

The invention relates in general to metal organic frameworks (MOFs) and their methods of preparation, and in particular to procedures for the preparation of MOFs using a substrate onto which MOF precursors are deposited.

### BACKGROUND OF THE INVENTION

Coordination polymers are a class of material formed from extended chains, sheets or networks of metal ions interconnected by ligands. Metal organic frameworks (MOFs) are highly ordered three-dimensional framework structures comprising inorganic nodes interconnected by organic ligands. MOFs have recently garnered significant attention because of their unprecedented surface area (approximately 10⁴ m²/g) and porosities (up to 90% of its free volume). Moreover, their structural diversity, arising from the vast number of possible combinations between the metal nodes and organic ligands/linkers, facilitates the tailoring of materials with widely different physical, chemical and geometrical properties for a vast array of applications, including catalysis, gas separation, sensing, charge transport and storage, and drug delivery, amongst others.

MOFs have conventionally been synthesized through a variety of techniques, including hydrothermal, solvothermal, microwave, sonochemical and electrochemical synthesis. However, there are a number of drawbacks associated with these routes, including scale-up limitations, difficulties adapting to industrial production, the need for activation of their pores prior to use, as well as the random orientation, polycrystallinity and defect-rich nature of the MOFs produced due to inhomogeneities in the diffusion process.

Some methods have been developed to improve structural control during crystal growth, primarily through liquid phase epitaxy, which involves growing crystals through stepwise layer-by-layer deposition of the coordination polymers and metal complexes on self-assembled monolayers.

Current methodologies have significant drawbacks. These include practical limitations in the large-scale production of these MOFs due to the excessive length of the synthesis process, which typically takes several days even with automation, and the requirement for subsequent post-synthesis chemical or thermal activation to remove the solvents trapped within the pores. In some instances, chemical activation via solvent exchange, for example, has often failed to yield the expected internal surface area. Moreover, the number of defects generally increases as the monolayers are grown, thus compromising the crystal orientation. In the case of freestanding MOFs, a further delamination step is required to release the oriented crystals from the substrate, which can often be challenging given that the usual thermal, mechanical or vapor exposure methods are prone to failure.

Additionally, a key aspect to realizing the high porosity and associated applications of MOFs is the removal of guest molecules from the framework while maintaining structural integrity. This process is generally referred to as “activation”. Conventional MOF activation strategies typically include heating under vacuum, solvent-exchange, supercritical CO₂ (scCO₂) exchange, freeze-drying, and chemical treatment. MOFs often require subsequent activation for application or derivatisation. Conventional activation methods under vacuum or via liquid solvent ex-change are either energy intensive or results in waste organic solvents that necessitate facilities for their treatment or disposal, particularly in large-scale manufacture. The present invention seeks to ameliorate one or more deficiencies with the current methods, or at least provide an alternative.

### SUMMARY OF THE INVENTION

The present invention provides a method of preparing a Metal Organic Framework (MOF) with an acoustically-driven microfluidic platform, the method comprising:
depositing a liquid comprising MOF precursors on a piezoelectric substrate of an acoustic microfluidic platform, the MOF precursors comprising a metal ion and an organic ligand;
applying acoustic irradiation to the liquid to induce azimuthal liquid recirculation, which causes formation of the MOF within the liquid, and
isolating the MOF.

The application of acoustic irradiation to the liquid comprising MOF precursors “to induce azimuthal liquid recirculation” inherently requires that the piezoelectric substrate is operated to generate and propagate acoustic waves asymmetrically across the substrate relative to the liquid. By “acoustic wave” is meant herein a mechanical vibration front that propagates elastically from one point of a medium to other points of the medium without giving the medium as a whole any permanent displacement. The transmission of these asymmetrical waves into the liquid comprising MOF precursors placed on the piezoelectric substrate results in an internal micro-centrifugal flow within the liquid, which in turn facilitates volumetric mixing of the precursors facilitating MOF formation. This is a significant departure from the conventional use of acoustically-driven microfluidic devices, in which the surface acoustic waves are induced to propagate symmetrically across the piezoelectric substrate. In those conventional systems, a liquid comprising MOF precursors deposited on the substrate would merely vibrate statically.

The methods described herein advantageously enable the formation of MOF crystals having a high degree of orientation and minimal number of defects. Specifically, the methods described herein can advantageously provide MOF crystals which are substantially aligned along the same crystallographic plane.

Advantageously, the methods described herein can provide activated MOFs without the need for a separate or subsequent activation step. This represents a significant advantage relative to conventional methods of preparing MOFs. In addition, the methods described herein can be characterized by improved efficiency relative to conventional MOF synthesis procedures, in that they can eliminate the need to isolate and subsequently activate the MOFs prior to use in other applications.

The present invention also provides an acoustically-driven microfluidic device for preparation of a Metal Organic Framework (MOF), the device comprising:
a piezoelectric substrate comprising a working surface for accommodating liquid comprising MOF precursors, the MOF precursors comprising a metal ion and an organic ligand, and
at least one interdigitated transducer (IDT) positioned off-centre relative to the working surface,
such that, when the device is in use, off-centred acoustic irradiation generated by the at least one IDTs induces azimuthal liquid recirculation in the liquid comprising MOF precursors, which causes formation of the MOF within the liquid.

The acoustic microfluidic platform comprises at least one off-centre IDT to induce, when the device is in use, recirculatory flow in the liquid. In some embodiments, the device comprises two or more opposing IDTs, wherein the IDTs are off-centre relative to the working surface. In those instances, the two or more opposing IDTs are off off-centre relative to the liquid, when the device is in use. The off-centre IDT(s) advantageously generate asymmetric acoustic waves, including asymmetric surface, bulk or hybrid acoustic wave irradiation relative to the working surface, such that recirculatory flow can be generated in a liquid comprising MOF precursors located in the working surface.

In some embodiments, the liquid comprising MOF precursors is in the form of a droplet. The liquid comprising MOF precursors may be delivered to the piezoelectric substrate from a receptacle, such as an open or closed microwell, channel or reservoir, via a delivery means, such as a tube, pipette, wick or any other dispenser.

In some embodiments, the acoustic irradiation of the described methods and device is a Rayleigh surface acoustic wave (SAW), shear-horizontal SAW, a bulk acoustic wave (e.g., a Lamb wave) or a hybrid wave that is a combination of the surface and bulk wave (e.g., a surface reflected bulk wave).

The described methods advantageously produce little to no heat and are of facile execution.

Advantageously, the application of acoustic irradiation to the liquid comprising MOF precursors to induce azimuthal liquid recirculation is conducive to MOF formation within the liquid in the absence of heat, for example at room temperature. As such, the methods afford MOF production without requiring the provision of heat to the liquid comprising MOF precursors, for example by coupling the piezoelectric substrate to an external heating source (e.g. a hot-plate) to provide heat to the liquid. In that regard, the methods of the invention represent a significant departure over existing procedures for synthesizing MOFs, which typically require the provision of heat from an external heating source (e.g. a hot-plate).

The invention also relates to a MOF prepared by the methods described herein. In some embodiments, the MOF is HKUST-1 (copper(II)-benzene-1,3,5-tricarboxylate).

### BRIEF DESCRIPTION OF THE DRAWINGS

Embodiments of the invention will be now described with reference to the following non-limiting drawings, in which:

FIG. 1 shows a schematic of an embodiment method using an embodiment device, outlining the rapid synthesis of highly-oriented and activated freestanding MOFs. FIG. 1(a) is a schematic depiction of the postulated mechanism by which the MOFs are synthesized using an embodiment acoustically-driven microfluidic device. FIGS. 1(b), (c) details a schematic depiction of the postulated mechanism comparing (b) a control experiment in the absence of the SAW irradiation and (c) an embodiment method using the embodiment devices depicted in the pictures on the right hand side,

FIG. 2 shows, per each row (i.e. a-a2, b-b2, c-c2, d-d2, e-e2), Scanning Electron Microscope (SEM, scale bars being 50 μm) images of HKUST-1 MOF crystals (a-e), average size determination plots (a1, b1, c1, d1, and e1), and corresponding X-Ray powder Diffraction (XRD) scans (a2, b2, c2, d2, and e2) obtained on the HKUST-1 MOF crystals for (a) control HKUST-1 MOF crystals synthesized under slow solvent evaporation as the control in the absence of acoustic excitation, and (b)-(e) HKUST-1 MOF crystals synthesized under increasing input voltages ((b) 1.5, (c) 4.5, (d) 7.5, and (e) 9 Vrms). The nature and scale of the x and y axis of plots a1, b1, c1, d1 correspond to those of plot e1, and the nature and scale of the x and y axis of plots a2, b2, c2, and d2 correspond to those of plot e2,

FIG. 3 shows schematic mechanisms ((a), (b) and corresponding XRD patterns (a1, b1) of oriented HKUST-1 MOF crystals prepared in accordance with the described methods,

FIG. 4 shows (a) image of sample HKUST-1 MOF crystals obtained in accordance to an embodiment procedure using 1.5 Vrms, 4.5 Vrms, and 9 Vrms input voltage, and (b) corresponding N₂ sorption isotherms, and

FIG. 5 shows (a) SEM, (b) XRD, (c) N₂ sorption isotherms, and (d) thermal gravimetric analysis (TGA) for Fe-MIL-88B MOF crystals obtained at an input voltages of 9 Vrms.

### DETAILED DESCRIPTION OF THE INVENTION

The present invention provides a method of preparing a Metal Organic Framework (MOF) with an acoustically-driven microfluidic platform, the method comprising:
depositing a liquid comprising MOF precursors on a piezoelectric substrate of an acoustic microfluidic platform, the MOF precursors comprising a metal ion and an organic ligand;
applying acoustic irradiation to the liquid to induce azimuthal liquid recirculation, which causes formation of the MOF within the liquid, and
isolating the MOF.

The present invention also provides an acoustically-driven microfluidic device for preparation of a Metal Organic Framework (MOF), the device comprising:
a piezoelectric substrate comprising a working surface for accommodating a liquid comprising MOF precursors, the MOF precursors comprising a metal ion and an organic ligand, and p1 at least one interdigitated transducer (IDT) positioned off-centre relative to the working surface,
such that, when the device is in use, off-centred acoustic irradiation generated by the at least one IDTs induces azimuthal recirculation in the liquid comprising MOF precursors, which causes formation of the MOF within the liquid.

In particular, the methods described provide rapid, simple and versatile access to MOFs which may be applied on an industrial scale.

The invention may also be said to provide a method of preparing metal organic frameworks with an acoustically-driven microfluidic platform, the method comprising: dissolving one or more types of metal precursors and one or more types of organic linker precursors in a working solution on a piezoelectric substrate of an acoustic microfluidic platform; applying acoustic irradiation to the working solution to induce azimuthal liquid recirculation; isolating the metal organic framework.

Further, the invention may also be said to provide an acoustically-driven microfluidic device for preparation of metal organic frameworks, the device comprising a piezoelectric substrate comprising a working surface for accommodating a working solution; at least one IDT positioned off-centre relative to the working solution, wherein off-centred acoustic irradiation generated by the at least one IDTs induces azimuthal liquid recirculation in the working solution on the working surface, to provide a metal organic framework.

In some embodiments, the described methods and device provide activated metal organic frameworks. As used herein, the terms “activate” and “activation” with respect to MOFs refers to the removal of guest molecules from the framework while maintaining structural integrity. Activation of the MOFs during synthesis advantageously avoids the need for further processing. The described methods thus represent a highly efficient synthesis for realizing activated, high porosity MOFs which may subsequently and immediately utilized in further applications. In an embodiment, the described methods simultaneously synthesize and activate the resultant MOFs. In particular, MOFs are synthesized and activated in a single step.

The device comprises at least one IDT. In some embodiments, the device comprises two or more opposing IDTs, wherein the IDTs are off-centre relative to the working surface. In those instances, the two or more opposing IDTs are off-centre relative to the liquid, when the device is in use. In some embodiments, the device comprises at least two or more IDTs in opposing directions, off-centre relative to the working sample.

As used herein, the term “off-centre” and variations thereof refers to displacement along a centre point or axis. In particular, the term “off-centre” when used in respect of IDTs, refers to where one or more IDTs is displaced from a centre axis, especially a centre axis which is aligned with a working surface designed to accommodate a liquid comprising MOF precursors. Off-centre IDTs advantageously enable generation of off-centre acoustic waves. In other words, the device described herein comprises at least one IDT, which is positioned off-centre relative to a working surface designed to accommodate a liquid comprising MOF precursors, to generate, when in use, off-centre acoustic waves such that only a portion of the liquid comprising MOF precursors is exposed to the irradiation.

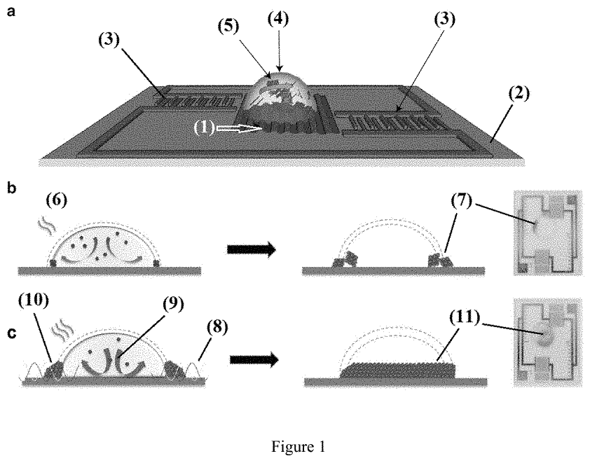

In some embodiments, the device includes at least two opposing IDTs off-centre relative to a centre axis which is aligned with a working surface designed to accommodate a liquid comprising MOF precursors. An example of such embodiments is shown in FIG. 1(a).

In an embodiment, the acoustic irradiation comprises surface acoustic waves (SAW). In another embodiment, the acoustic irradiation comprises bulk acoustic waves (BAW). In yet another embodiment, the acoustic irradiation comprises hybrid acoustic waves, that is, acoustic waves comprising both surface and bulk acoustic waves.

In an embodiment, the acoustic irradiation is Rayleigh SAW. In another embodiment, the acoustic irradiation is a shear-horizontal SAW.

It is appreciated that the acoustic irradiation, including SAW or BAW, may further be characterized as either travelling or standing acoustic waves. In one or more embodiments, the acoustic radiation may include travelling SAW waves, travelling BAW waves, standing SAW waves, standing BAW waves and combinations thereof

Without wishing to be bound by theory, the use of off-centre acoustic waves leads to breaking the symmetry of the waves, hence producing a convective flow current in a liquid sample provided on the working surface of the piezoelectric substrate which is substantially similar to micro-centrifugation. The inventors have found that off-centre acoustic waves enable the preparation of MOF crystals having a high degree of orientation. That is, the described method advantageously provides MOFs wherein the crystals are substantially aligned in the same plane high degree of orientation. Further, the described methods and device advantageously provide MOF crystals with a reduced number of defects.

By way of example, in one embodiment, Rayleigh SAW excitation may induce azimuthal flow driving turbulent convective transport of solute molecules in a liquid comprising MOF precursors located on the working surface of the piezoelectric substrate. This in turn leads to homogeneous deposition of successive stacks of solute monolayers within this highly concentrated region to form MOFs. Aided by the evanescent electric field from the SAW, this results in vertical-oriented stacking of the monolayers of the MOF, culminating in a large, highly-ordered superlattice structure. Advantageously, the described method and device provide MOFs having a high degree of orientation, that is, they comprise highly-ordered superlattices. This is evident from powder XRD data, which clearly indicates reflection of parallel planes in the resultant crystals.

Further, the described methods are advantageously facile. In an embodiment, the described methods may be conducted at a temperature below about 50° C., preferably below about 40° C., more preferably below about 30° C. more preferably below about 25° C., more preferably below about 20° C. In particular, the described methods may be conducted at room temperature. In an embodiment, the described methods may be carried out at a temperature in the range of from 273° C. to 200° C.

The process of the invention may be carried out at any pressure conducive to MOF formation. In some embodiments, the process is conducted at a pressure in the range from 0 to 100 bars (absolute pressure), for example 2 to 5 bar, or at atmospheric pressure.

The described methods are advantageously scalable. For example, the method may be performed using a liquid comprising MOF precursors at nanogram scale, at microgram scale, or at gram scale. In some embodiments, the methods is performed using a liquid comprising MOF precursors at a multigram scale, at kilogram scale, or at multi-kilogram scale. In an embodiment, the methods may be applied on an industrial scale.

The described methods are advantageously fast and efficient. In an embodiment, the reaction time is less than 5 hours, preferably less than 4 hours, preferably less than 3 hours, preferably less than 2 hours, preferably less than 1 hour, preferably less than 45 mins, preferably less than 30 mins, preferably less than 20 mins, preferably less than 15 mins, preferably less than 10 mins, preferably less than 5 mins, preferably less than 3 mins, preferably less than 2 mins, preferably less than 1 min, preferably less than 30 seconds, preferably less than 20 seconds, preferably less than 10 seconds, preferably less than 5 seconds, preferably less than 1 second.

In some embodiments, the liquid comprising MOF precursors is in the form of a droplet. In some embodiments, the liquid comprising MOF precursors is delivered to the piezoelectric substrate from a receptacle, such as an open or closed microwell, channel or reservoir, via a delivery means, such as a tube, pipette, wick or any other dispenser. This can advantageously achieve continuous production of MOFs.

The piezoelectric substrate for use in the invention may be made of any piezoelectric material that is capable of generating acoustic waves in response to an applied electrical input. The piezoelectric material may include a metallic oxide or an insulating material. In that regard, the piezoelectric substrate may be made of a piezoelectric material that comprises, for example, lithium niobate (LiNbO₃), lithium tantalate (LiTaO₃), lithium tetraborate (Li₂B₄O₇), barium titanate (BaTiO₃), lead zirconate (PbZrO₃), lead titanate (PbTiO₃), lead zirconate titanate (PZT), zinc oxide (ZnO), gallium arsenide (GaAs), quartz, niobate, or a combination thereof. In some embodiments, the piezoelectric substrate is made of lithium tantalate (LiTaO₃) or lithium niobate (LiNbO₃). In some embodiments, the piezoelectric substrate is made of a single crystal piezoelectric material.

As a skilled person would know, generation of acoustic irradiation in a piezoelectric substrate requires the application of an input voltage to the substrate, for example by applying an input voltage to one or more IDTs located on the substrate. In that regard, for the purpose of the present invention the input voltage may be any input voltage that does not induce nebulization of the liquid comprising MOF precursors. In some embodiments, the input voltage of the described methods and device is less than 40 Vᵣₘₛ, preferably less than less than 30 Vᵣₘₛ, preferably less than 20 Vᵣₘₛ, preferably less than 10 Vᵣₘₛ, preferably less than 9 Vᵣₘₛ, preferably less than 7.5 Vᵣₘₛ, preferably less than 4.5 Vᵣₘₛ, and preferably less than 1.5 Vᵣₘₛ.

MOFs typically comprise at least two components, i.e. a metal ion or cluster of metal ions and one or more organic ligands or linkers. The choice of metal precursor and organic linker dictates the structure, properties and potential applications of the resultant MOF. The described methods and device may be used for preparation of a range of different MOFs. In an embodiment, the metal organic frameworks may be surface anchored metal organic frameworks. In an embodiment, the metal organic frameworks may be free standing oriented films. In particular, the described methods and device may be used with a range of metal ions or metal precursors. Furthermore, the described methods and device may be used with a range of organic ligands or linker precursors.

In one aspect, there is provided a MOF prepared by the methods described herein.

The procedure of the invention is based on the provision of a liquid comprising MOF precursors. In that regard, MOF precursors suitable for use in the invention include those compounds known in the art that provide (i) the ions of metals listed herein and (i) organic ligands of the kind described herein.

In some embodiments, the one or more types of metal precursors are selected from precursors of elements of groups Ia, IIa, IIIa, IVa to VIIIa and Ib and VIb of the Periodic Table of the Elements. Suitable precursors may be a salt of the relevant metal ion. Examples in that regard include metal-chlorides, -nitrates, -acetates -sulphates, -hydrogen sulphates, -bromides, -carbonates, -phosphates, and derivatives thereof, including mono- and polyhydrate derivatives.

In some embodiments, the metal precursors comprise one or more salts selected from a salt of Cu, Ni, Fe, Co, Zn, Mn, Ru, Mo, Cr, W, Rh and Pd. In an embodiment, the metal precursors comprise Cu, salts and ions thereof. In an embodiment, the metal precursor is copper(II) nitrate. In an embodiment, the one or more types of metal precursor is Fe, salts and ions thereof.

Examples of suitable metal salt precursors include, but are not limited to, cobalt nitrate (Co(NO₃)₂.xH₂O), zinc nitrate (Zn(NO₃)₂.xH₂O), iron(III) nitrate (Fe(NO₃)₃.xH₂O), aluminium nitrate (Al(NO₃)₃.xH₂O), magnesium nitrate (Mg(NO₃)₂.xH₂O), calcium nitrate (Ca(NO₃)₂.xH₂O), beryllium nitrate (Be(NO₃)₂.xH₂O), europium nitrate (Eu(NO₃)₃.xH₂O), terbium nitrate (Tb(NO₃)₃.xH₂O), ytterbium nitrate (Yb(NO₃)₃.xH₂O), dysprosium nitrate (Dy(NO₃)₃.xH₂O), erbium nitrate (Er(NO₃)₃.xH₂O), gallium nitrate (Ga(NO₃)₃.xH₂O), gadolinium nitrate (Gd(NO₃)₃.xH₂O), nickel nitrate (Ni(NO₃)₂.xH₂O), lead nitrate (Pb(NO₃)₂.xH₂O), cadmium nitrate (Cd(NO₃)₂.xH₂O), manganese(II) nitrate (Mn(NO₃)₂.xH₂O), cobalt chloride (CoCl₂.xH₂O), zinc chloride (ZnCl₂.xH₂O), iron(III) chloride (FeCl₃.xH₂O), iron(II) chloride (FeCl₂.xH₂O), aluminium chloride (AlCl₃.xH₂O), magnesium chloride (MgCl₂.xH₂O), calcium chloride (CaCl₂.xH₂O), beryllium chloride (BeCl₂.xH₂O), europium chloride (EuCl₃.xH₂O), terbium chloride (TbCl₃.xH₂O), ytterbium chloride (YbCl₃.xH₂O), dysprosium chloride (DyCl₃.xH₂O), erbium chloride (ErCl₃.xH₂O), gallium chloride (GaCl₃.xH₂O), gadolinium chloride (GdCl₃.xH₂O), nickel chloride (NiCl₂.xH₂O), lead(II) chloride (PbCl₂.xH₂O), cadmium chloride (CdCl₂.xH₂O)), manganese(II) chloride (MnCl₂.xH₂O), cobalt acetate (Co(CH₃COO)₂.xH₂O), zinc acetate (Zn(CH₃COO)₂.xH₂O), iron(III) acetate (Fe(CH₃COO)₃.xH₂O), iron(II) acetate (Fe(CH₃COO)₂.xH₂O), aluminium acetate (Al(CH₃COO)₃.xH₂O), magnesium acetate (Mg(CH₃COO)₂.xH₂O), calcium acetate (Ca(CH₃COO)₂.xH₂O), beryllium acetate (Be(CH₃COO)₂.xH₂O), europium acetate (Eu(CH₃COO)₃.xH₂O), terbium acetate (Tb(CH₃COO)₃.xH₂O), ytterbium acetate (Yb(CH₃COO)₃.xH₂O), dysprosium acetate (Dy(CH₃COO)₃.xH₂O), erbium acetate (Er(CH₃COO)₃.xH₂O), gallium acetate (Ga(CH₃COO)₃.xH₂O), gadolinium acetate (Gd(CH₃COO)₃.xH₂O), nickel acetate (Ni(CH₃COO)₂.xH₂O), lead(II) acetate (Pb(CH₃COO)₂.xH₂O), cadmium acetate (Cd(CH₃COO)₂.xH₂O)), manganese(II) acetate (Mn(CH₃COO)₂.xH₂O), cobalt sulphate (CoSO4.xH₂O), zinc sulphate (ZnSO₄.xH₂O), iron(III) sulphate (Fe₂(SO4)₃.xH₂O), iron(II) sulphate (FeSO4.xH₂O), aluminium sulphate (Al₂(SO4)₃.xH₂O), magnesium sulphate (MgSO4.xH₂O), calcium sulphate (CaSO4.xH₂O), beryllium sulphate (BeSO4.xH₂O), europium sulphate (Eu₂(SO4)₃.xH₂O), terbium sulphate (Tb₂(SO4)₃.xH₂O), ytterbium sulphate (Yb₂(SO4)₃.xH₂O), dysprosium sulphate (Dy₂(SO4)₃.xH₂O), erbium sulphate (Er₂(SO4)₃.xH₂O), gallium sulphate (Ga₂(SO4)₃.xH₂O), gadolinium sulphate (Gd₂(SO4)₃.xH₂O), nickel sulphate (NiSO4.xH₂O), lead sulphate (PbSO4.xH₂O), cadmium sulphate (CdSO4.xH₂O), manganese(II) sulphate (MnSO₄.xH₂O), cobalt hydroxide (Co(OH)₂.xH₂O), zinc hydroxide (Zn(OH)₂.xH₂O), iron(III) hydroxide (Fe(OH)₃.xH₂O), iron(III) oxide:hydroxide (FeO(OH).xH₂O), Iron(II) hydroxide (Fe(OH)₂.xH₂O), aluminium hydroxide (Al(OH)₃.xH₂O), magnesium hydroxide (Mg(OH)₂.xH₂O), calcium hydroxide (Ca(OH)₂.xH₂O), beryllium hydroxide (Be(OH)₂.xH₂O), europium hydroxide (Eu(OH)₃.xH₂O), terbium hydroxide (Tb(OH)₃.xH₂O), ytterbium hydroxide (Yb(OH)₃.xH₂O), dysprosium hydroxide (Dy(OH)₃.xH₂O), erbium hydroxide (Er(OH)₃.xH₂O), gallium hydroxide (Ga(OH)₃.xH₂O), gadolinium hydroxide (Gd(OH)₃.xH₂O), nickel hydroxide (Ni(OH)₂.xH₂O), lead hydroxide (Pb(OH)₂.H₂O), cadmium hydroxide (Cd(OH)₂.xH₂O), manganese(II) hydroxide (Mn(OH)₂.xH₂O), cobalt bromide (CoBr₂.xH₂O), zinc bromide (ZnBr₂.xH₂O), iron(III) bromide (FeBr₃.xH₂O), iron(II) bromide (FeBr₂.xH₂O), aluminium bromide (AlBr₃.xH₂O), magnesium bromide (MgBr₂.xH₂O), calcium bromide (CaBr₂. xH₂O), beryllium bromide (BeBr₂.xH₂O), europium bromide (EuBr₃.xH₂O), terbium bromide (TbBr₃.xH₂O), ytterbium bromide (YbBr₃.xH₂O), dysprosium bromide (DyBr₃.xH₂O), erbium bromide (ErBr₃.xH₂O), gallium bromide (GaBr₃.xH₂O), gadolinium bromide (GdBr₃.xH₂O), nickel bromide (NiBr₂.xH₂O), lead bromide (PbBr₂.xH₂O), cadmium bromide (CdBr₂.xH₂O), manganese(II) bromide (MnBr₂.xH₂O), cobalt carbonate (CoCO₃.xH₂O), zinc carbonate (ZnCO₃.xH₂O), iron(III) carbonate (Fe₂(CO₃)₃.xH₂O), aluminium carbonate (Al₂(CO₃)₃.xH₂O), magnesium carbonate (MgCO₃.xH₂O), calcium carbonate (CaCO₃.xH₂O), beryllium carbonate (BeCO₃.xH₂O), europium carbonate (Eu₂(CO₃)₃.xH₂O), terbium carbonate (Tb₂(CO₃)₃.xH₂O), ytterbium carbonate (Yb₂(CO₃)₃.xH₂O), dysprosium carbonate (Dy₂(CO₃)₃.xH₂O), erbium carbonate (Er₂(CO₃)₃.xH₂O), gallium carbonate (Ga₂(CO₃)₃.xH₂O), gadolinium carbonate (Gd₂(CO₃)₃.xH₂O), nickel carbonate (NiCO₃.xH₂O), lead carbonate (PbCO₃.xH₂O), cadmium carbonate (CdCO₃.xH₂O), manganese(II) carbonate (MnCO₃.xH₂O), and mixtures thereof, where x ranges range from 0 to 12.

In some embodiments, the metal precursor is used in a concentration which is generally in the range of from 0.1 nM to 100 M.

With regard to the organic ligand, examples of organic ligand precursors include, but are not limited to, 4,4′,4″-[benzene-1,3,5-triyl-tris(ethyne-2,1-diyl)]tribenzoate, biphenyl-4,4′-dicarboxylate, 4,4′,4″-[benzene-1,3,5-triyl-tris(benzene-4,1-diyl)]tribenzoate, 1,3,5-benzenetribenzoate, 1,4-benzenedicarboxylate, benzene-1,3,5-tris(1H-tetrazole), 1,3,5-benzenetricarboxylic acid, terephthalic acid, imidazole, benzimidazole, 2-nitroimidazole, 2-methylimidazole (HmIm), 2-ethylimidazole, 5-chloro benzimidazole, purine, fumaric acid, α-cyclodextrin, β-cyclodextrin, γ-cyclodextrin 1,4-Bis(1-imidazolyl)benzene), 4,4′-Bispyridyl, 1,4-Diazabicyclo[2.2.2]octane, 2-amino-1,4-benzenedicarboxylate, 2-amino-1,4-benzenedicarboxylic acid, 4,4′-Azobenzenedicarboxylate, 4,4′-Azobenzenedicarboxylic acid, Aniline-2,4,6-tribenzoate, Aniline-2,4,6-tribenzic acid, Biphenyl-4,4′-dicarboxylic acid, 1,1′-Biphenyl-2,2′,6,6′-tetracarboxylate, 1,1′-Biphenyl-2,2′,6,6′-tetracarboxylic acid, 2,2′-Bipyridyl-5,5′-dicarboxylate, 2,2′-Bipyridyl-5,5′-dicarboxylic acid, 1,3,5-Tris(4-carboxyphenyl)benzene, 1,3,5-Tris(4-carboxylatephenyl)benzene, 1,3,5-Benzenetricarboxylate, 2,5-Dihydroxy-1,4-benzenedicarboxylate, 2,5-Dihydroxy-1,4-benzenedicarboxylic acid, 2,5-Dimethoxy-1,4-benzenedicarboxylate, 2,5-Dimethoxy-1,4-benzenedicarboxylic acid, 1,4-Naphthalenedicarboxylate, 1,4-Naphthalenedicarboxylic acid, 1,3-Naphthalenedicarboxylate, 1,3-Naphthalenedicarboxylic acid, 1,7-Naphthalenedicarboxylate, 1,7-Naphthalenedicarboxylic acid, 2,6-Naphthalenedicarboxylate, 2,6-Naphthalenedicarboxylic acid, 1,5-Naphthalenedicarboxylate, 1,5-Naphthalenedicarboxylic acid, 2,7-Naphthalenedicarboxylate, 2,7-Naphthalenedicarboxylic acid, 4,4′,4″-Nitrilotrisbenzoate, 4,4′,4″-Nitrilotrisbenzoic acid, 2,4,6-Tris(2,5-dicarboxylphenylamino)-1,3,5-triazine, 2,4,6-Tris(2,5-dicarboxylatephenylamino)-1,3,5-triazine, 1,3,6,8-Tetrakis(4-carboxyphenyl)pyrene, 1,3,6,8-Tetrakis(4-carboxylatephenyl)pyrene, 1,2,4,5-Tetrakis(4-carboxyphenyl)benzene, 1,2,4,5-Tetrakis(4-carboxylatephenyl)benzene, 5,10,15,20-Tetrakis(4-carboxyphenyl)porphyrin, 5,10,15,20-Tetrakis(4-carboxylatephenyl)porphyrin, adenine, adeninate, fumarate, 1,2,4,5-benzenetetracarboxylate, 1,2,4,5-benzenetetracarboxylic acid, 1,3,5-benzenetribenzoic acid, 3-amino-1,5-benzenedicarboxylic acid, 3-amino-1,5-benzenedicarboxylate, 1,3-benzenedicarboxylic acid, 1,3-benzenedicarboxylate, 4,4′,4″-[benzene-1,3,5-triyl-tris(ethyne-2,1-diyl)]tribenzoic acid, 4,4′,4″-[benzene-1,3,5-triyl-tris(benzene-4,1-diyl)]tribenzoic acid, pyrazole, 2,5-dimethylpyrazole, 1,2,4-triazole, 3,5-dimethyl-1,2,4-triazole, pyrazine, 2,5-dimethylpyrazine, hexamethylentetraamine, nicotinic acid, nicotinate, isonicotinic acid, isonicotinate, 4-(3,5-dimethyl-1H-pyrazole)-benzoic acid, 2,5-furandicarboxylic acid, 2,5-furandicarboxylate, 3,5-dimethyl-4-carboxypyrazole, 3,5-dimethyl-4-carboxylatepyrazole, 4-(3,5-dimethyl-1H-pyrazol-4-yl)-benzoic acid, 4-(3,5-dimethyl-1H-pyrazol-4-yl)-benzoate, and mixtures thereof.

It will be understood that the organic ligands can also be functionalised organic ligands. For example, any one of the organic ligands listed herein may be additionally functionalised by amino-, such as 2-aminoterephthalic acid, urethane-, acetamide-, or amide-. The organic ligand can be functionalised before being used as precursor for MOF formation, or alternatively the assembled MOF itself can be chemically treated to functionalise its bridging organic ligands.

In some embodiments, the organic ligand is selected from mono-, di-, tri-, and tetravalent organic ligands, or a combination thereof. In some embodiments, the organic ligand is selected from trimesic acid, and 1,4-benzenedicarboxylic acid (BDC).

A skilled person will be aware of suitable chemical protocols that allow functionalizing MOFs with functional groups, either by pre-functionalizing organic ligands used to synthesize MOFs or by post-functionalizing pre-formed MOFs.

Suitable functional groups that may be provided on the MOF include —NHR, —N(R)₂, —NH₂, —NO₂, —NH(aryl), halides, aryl, aralkyl, alkenyl, alkynyl, pyridyl, bipyridyl, terpyridyl, anilino, —O(alkyl), cycloalkyl, cycloalkenyl, cycloalkynyl, sulfonamido, hydroxyl, cyano, —(CO)R, —(SO₂)R, —(CO₂)R, —SH, —S(alkyl), —SO³H, —SO³⁻M⁺, —COOH, COO⁻M⁺, —PO₃H₂, —PO₃H⁻M⁺, —PO3²⁻M²⁺, —CO₂H, silyl derivatives, borane derivatives, ferrocenes and other metallocenes, where M is a metal atom, and R is C₁₋₁₀ alkyl.

Provided the MOF forms, the liquid comprising MOF precursors may comprise any amount of MOF precursors.

In that regard, concentrations of MOF precursors in the liquid can include a range between about 0.001 M and 1 M, between about 0.01 M and 0.5 M, between about 0.01 M and 0.2 M, between about 0.02 M and 0.2 M, between about 0.02 M and 0.15 M, between about 0.05 M and 0.15 M, between about 0.08 M and 0.16 M. The values refer to concentration of organic ligand as well as concentration of metal salt, relative to the total volume of the liquid comprising the MOF precursors.

The organic ligand and metal iron precursor may be used according to any relative amount that is conducive to MOF formation. In some embodiments, the organic ligand to metal molar ratio may range from 60:1 to 1:60, from 30:1 to 1:30, from 10:1 to 1:10, from 5:1 to 1:5, from 2.5:1 to 1:2.5, from 2:1 to 1:2, or from 1.5:1 to 1:1.5. In some embodiments, the organic ligand to metal molar ratio is from 0.1:1 to 1:1, from 0.25:1 to 1:1, from 0.5:1 to 1:1, or from 0.75:1 to 1:1. For example, the organic ligand to metal molar ratio may be about 0.5:1.

In an embodiment, the organic ligand or linker is used in any suitable concentration, for example, in the range of from 0.5 to 90% by weight.

In particular embodiments, the one or more types of metal precursor is copper (II) nitrate and one or more types of organic ligand or linker is trimesic acid. In particular embodiments, the MOF is HKUST-1 [Cu3(1,3,5-benzenetricarboxylate)n, also known as copper(II)-benzene-1,3,5-tricarboxylate].

In an embodiment, the one or more types of metal precursor is Fe, salts and ions thereof. In another embodiment, the MOF is Fe-MIL-88.

In the context of the invention, the liquid comprising MOF precursors may be any composition of MOF precursors of the kind described herein that presents in liquid form, and from which MOF can precipitate upon interaction of the precursors.

For example, a liquid comprising MOF precursors for the purpose of the invention may be a solution resulting from dissolving MOF precursors of the kind described herein into a suitable solvent. Suitable solvents may be any suitable solvent or solvent mixtures in which one or more metal precursors and organic ligand or linker precursor can be at least partly dissolved or suspended. Examples of preferred solvents include but are not limited to water; alcohols; carboxylic; nitrites; ketones; halogenated solvents; amines; amides; dimethyl sulfoxide; aromatic and heteroaromatic solvents; or mixtures thereof. In some embodiments, the liquid comprising MOF precursors comprises water. In some embodiments, the liquid comprising MOF precursors comprises an alcohol or water, and combinations thereof. In some embodiments, the liquid comprising MOF precursors comprises ethanol and water. The term “solvent” as used above includes both pure solvents and solvents which comprise small amounts of at least one further compound such as, for example, water.

The liquid comprising MOF precursors may be adjusted to any pH appropriate for the synthesis or the stability of the metal organic framework. For example, the pH may be adjusted by addition of one or more acids, bases or salts.

The methods and device described may be further understood with reference to the accompanying Figures.

FIG. 1 details a schematic representation of the described acoustically-driven microfluidic platform. As detailed in FIG. 1(a), opposing SAWs (1) are generated on a piezoelectric substrate (2) by applying an input voltage to a pair of offset IDTs (3) patterned on the substrate. This results in the generation of asymmetric SAWs (1) that travel to a drop of liquid (4) comprising MOF precursors. The interaction between the asymmetric waves and the solution promotes microcentrifugation flow within the droplet, which drives the subsequent precipitation and nucleation of the MOF crystals (5) within it.

FIG. 1(b) details a schematic depiction of the postulated mechanism, relative to a reference mechanism in which SAWs are not generated. Specifically, FIG. 1(b) is a schematic of a control experiment performed in the absence of SAW irradiation. In that case, slow solvent evaporation (sessile drop evaporation (6)) leads to a weak convection cell in the drop, which transports the solute molecules to its contact line, where they precipitate to form a ring of crystals (coffee-ring effect (7)). The slow diffusion-dominated process culminates in a dilute solute concentration in the contact line region, and therefore the crystals that form lack long-range ordering.

FIG. 1(c) details the acoustically driven assembly of MOF in accordance with an embodiment of the methods disclosed herein, wherein under Rayleigh SAW excitation (8), microcentrifugation flow (9) is induced which drives fast turbulent convective transport of the solute molecules to the contact line, whose oscillation smears out the ring of crystals (10), leading to homogeneous deposition of successive stacks of solute monolayers within this highly concentrated region. Aided by the evanescent electric field from the SAW, this results in vertical-oriented stacking of the monolayers, culminating in a large, highly-ordered superlattice MOF structure (11).

The schematic of FIG. 1(c) allows to appreciate that by inducing azimuthal liquid recirculation, the acoustic irradiation does not promote nebulization of the liquid. Instead, a microcentrifugation flow is induced within the liquid and MOF precipitates within the liquid and is deposited along the contact line between the liquid and the substrate as the liquid recedes. The contact line recedes as the solvent evaporates from the spinning solution, leaving a homogeneous layer of MOF crystals on the surface of the substrate. During that process, the liquid comprising MOF precursors maintains a droplet shape.

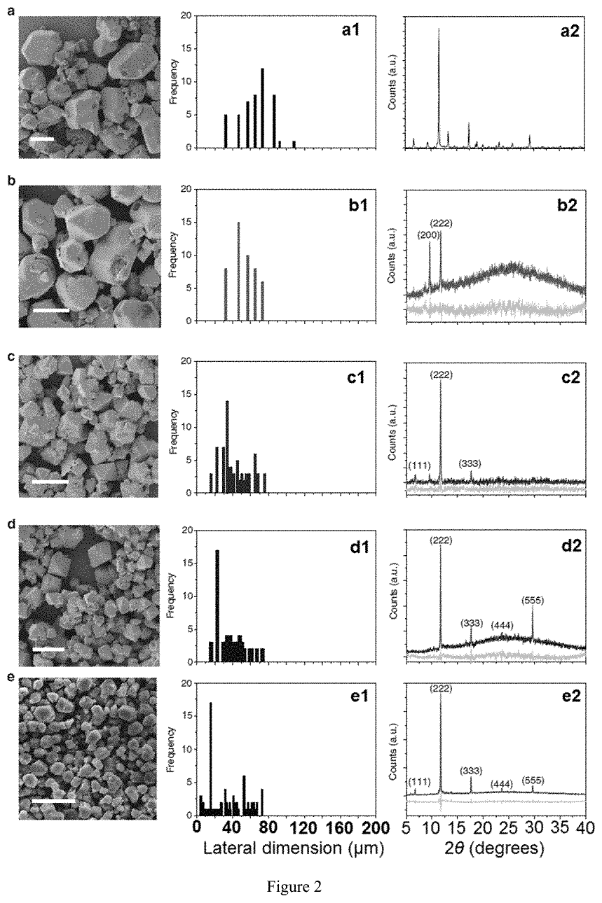

FIG. 2 shows, per each row(i.e. a-a2, b-b2, c-c2, d-d2, e-e2), Scanning Electron Microscope (SEM, scale bars being 50 μm) images of HKUST-1 MOF crystals (a-e), average size determination plots (a1, b1, c1, d1, and e1) through lateral size frequency distributions, and corresponding X-Ray powder Diffraction (XRD) scans (a2, b2, c2, d2, and e2) obtained on the HKUST-1 MOF crystals for (a) control HKUST-1 MOF crystals synthesized under slow solvent evaporation as the control in the absence of acoustic excitation, and (b)-(e) HKUST-1 MOF crystals synthesized under increasing input voltages ((b) 1.5, (c) 4.5, (d) 7.5, and (e) 9 Vrms).

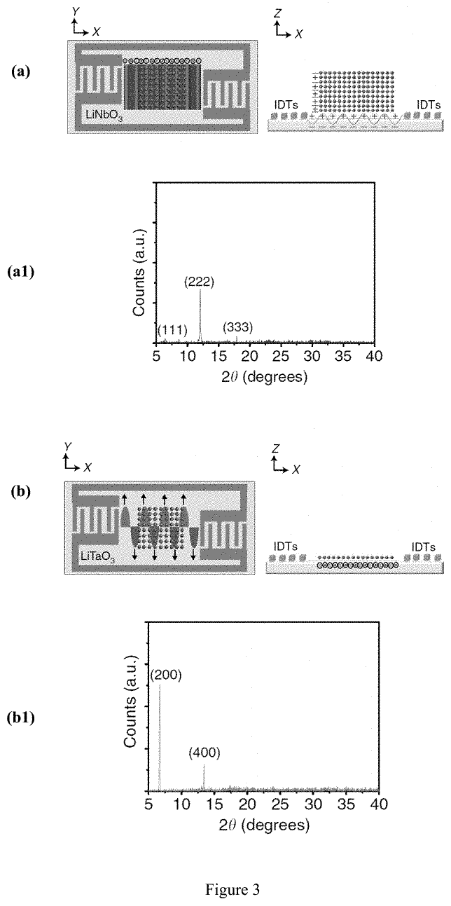

FIG. 3 details the mechanism by which oriented HKUST-1 MOFs are synthesized under the acoustoelectric excitation. Specifically, FIGS. 3(a) and (b) represents top and side view schematics (not to scale), and corresponding powder XRD spectra (FIGS. 3(a1) and 3(b1) of HKUST-1 MOF crystals synthesized under (a) Rayleigh SAW and (b) SH-SAW excitation at 4.5 Vrms.

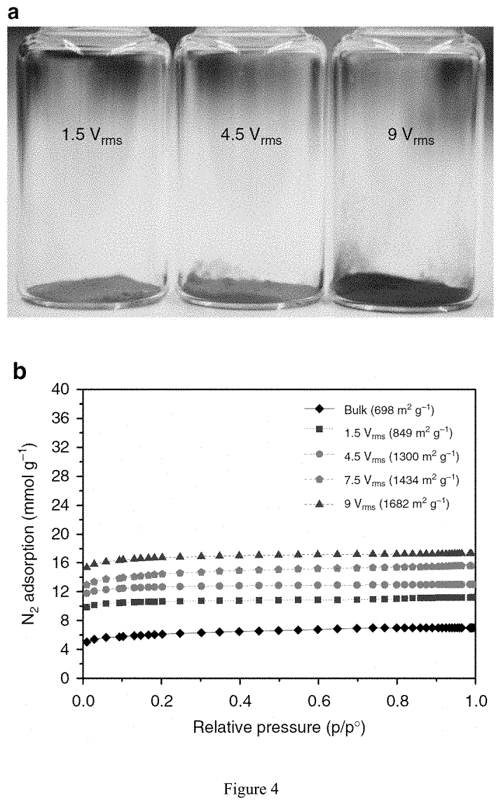

FIG. 4 details characterization of the activation and surface area of the synthesized HKUST-1 MOFs. Specifically, FIG. 4(a) represents images of MOF crystals prepared under Rayleigh SAW excitation. The MOFs are darker as the input voltage applied to the substrate was increased from 1.5 Vrms, 4.5 Vrms, to 9 Vrms (it was observed that the color varies from a solvent-rich light blue shade to a solvent-poor dark blue shade depending on the input voltage). This indicates that the crystals are progressively activated simultaneously during the synthesis as the intensity of the acoustic energy into the drop is increased. FIG. 4 (b) represents N₂ sorption isotherms for the HKUST-1 MOFs synthesized at increasing voltages compared to that for bulk HKUST-1 produced in the absence of acoustic irradiation (bottom line). The N₂ sorption increases for MOFs produced under progressively higher input voltages.

The unique physicochemical properties of MOFs ensure a wide range of potential applications. Accordingly, MOFs prepared in accordance with the described methods may be used in an array of applications including but not limited to, catalysis, gas storage, imaging, energy storage, carbon capture, separation, and drug delivery.

The methods and device described may be further illustrated with reference to the accompanying Examples.

### EXAMPLES

Example 1

### Device

The acoustomicrofluidic device shown in FIG. 1(a) consists of a piezoelectric substrate that comprises either 127.68 Y X lithium niobate (LiNbO₃; Roditi Ltd., London, UK) for the Rayleigh SAW experiments, or, YX lithium tantalate (LiTaO₃; Fujitsu Laboratories Ltd., Atsugi, Japan) for the SH-SAW experiments, on which an off-centered pair of 300 nm thick straight aluminium interdigitated transducers (IDTs) in a basic full-width interleaved configuration are patterned atop a 20 nm thick chromium layer using sputter deposition and standard UV photolithography.

The substrates were optically polished on both sides to render it transparent such that the interior of the fluid drop can be observed from the underside of the device to avoid optical distortion at the liquid air interface of the drop when visualizing from above. Each IDT consists of 25 finger pairs with an aperture of 12 mm and a gap and width of 110 μm, such that application of a sinusoidal electrical signal through an RF signal generator (N9310A; Agilent Technologies, Santa Clara, Calif., USA) and amplifier (10W1000C; Amplifier Research, Souderton, Pa., USA) at their resonant frequency of 19.37 MHz gives rise to a Rayleigh SAW (in the case of the LiNbO₃ substrate) or a SH-SAW (in the case of the LiTaO₃ substrate) with a wavelength of 200 μm.

A variety of input voltages (1.5, 4.5, 7.5 and 9 Vrms) to the electrical signal was used in the study, but this was limited to an upper value of 9 Vrms to avoid the liquid being nebulized off the device.

### Working Solution of MOF Precursors

Working solutions were prepared by dissolving the metal precursor, i.e., 0.875 g (3.62 mmol) copper(II) nitrate hemi(pentahydrate) (Cu(NO₃)₂.2:5H₂O; Sigma Aldrich Pty. Ltd., Castle-Hill, NSW, Australia), and the organic ligand precursor, i.e., 0.42 g (2 mmol) trimesic acid (C₆H₃(CO₂H)₃; Sigma Aldrich Pty. Ltd., Castle-Hill, NSW, Australia), in two separate tubes containing 12 ml 1:1 (vol/vol) ethanol (Sigma Aldrich Pty. Ltd., Castle-Hill, NSW, Australia) and MilliQ water (18.2 MΩcm, Merck Millipore, Bayswater, VIC, Australia) each.

A 10 μl drop of this solution was then carefully pipetted onto the middle of the device such that one-half of the drop was subjected to the SAW irradiation in one direction from one IDT and the other half was subjected to the SAW irradiation from the opposite direction from the other IDT. Due to this asymmetry, an azimuthal microcentrifugation flow is generated within the drop (FIG. 1(a)). After 5 mins of exposure to the SAW excitation for each input voltage, during which the MOF was observed to nucleate and hence crystallize, the MOF powder was subsequently collected from the device in an Eppendorf tube (Eppendorf South Pacific Pty. Ltd., North Ryde, NSW, Australia) and reconstituted with 1:1 (vol/vol) ethanol/water to make a 1 ml solution. This suspension was then centrifuged at 5000 rpm for 5 min and thrice washed in 50% ethanol/water, following which it was left to dry at 25° C. in a sealed glass vial prior to further analysis.

### Example 2 (Comparative)

### Conventional Preparation of Bulk HKUST-1

As a comparative control, bulk HKUST-1 was prepared using a conventional hydrothermal synthesis wherein which 0.42 g (2 mmol) BTC was dissolved in 24 ml of 1:1 (vol/vol) ethanol/water. The mixture was stirred for 10 min until a clear solution was obtained. Subsequently, 0.875 g (3.62 mmol) of (Cu(NO₃)₂.2:5H₂O was added to the mixture, followed by agitation for a further 10 mins. Once the reactants were completely dissolved in the solvent, the resulting blue solution was left to evaporate to allow the crystallisation to occur, through which a blue crystalline powder was obtained. The powder was then washed thrice with 60 ml of a 1:1 (vol/vol) ethanol/water solution and the product left to dry at 25° C. in a sealed glass vial for further analysis.

### Example 3

### Analysis

SEM imaging (Philips XL30, FEI, Hillsboro, Oreg., USA) was employed to characterize the morphology of the MOF crystals. Briefly, the crystals were deposited on a silicon wafer above which a 5 nm gold layer was sputtered over 60 s and imaging was carried out at 10 kV. The size of the MOF crystals was determined through visual inspection of the SEM digital images using ImageJ (v.1.34, National Institutes of Health, Bethesda, Md., USA).

To resolve the crystal structure, powder XRD (D8 Advance, Bruker Pty. Ltd., Preston, VIC, Australia) was conducted with Cu K radiation at 40 mA and 40 kV (=1.54 Å) at a scan rate of 2 min, step size of 0.02, and 2θ range of 6° to 50° FTIR analysis of the samples at room temperature were acquired using a spectrophotometer (Spectrum One; PerkinElmer Inc., Waltham, Mass., USA) by placing a 10⁻¹ suspension of the crystals on a diamond substrate, from which transmittance measurements were conducted in the wavenumber range between 500 and 4000 cm⁻¹.

The thermal properties of the crystals were analyzed through TGA (Pyrus 1, PerkinElmer Inc., Waltham, Mass., USA). Specifically, 7.5 mg of the crystals were placed in an aluminium stainless-steel pan and heated at a rate of 10° C./min under N₂ from 35° C. to 800° C. The BET and Langmuir surface areas were calculated from nitrogen physiosorption measurements by placing approximately 0.5 g of the crystals in a surface area and porosity analyzer (ASAP 2020; Micromeritics Instrument Corp. Norcross, Ga., USA) under N₂ at 25° C. for 12 hrs. To quantify the overall yield and production rate, the dried MOF powder was weighed using a microbalance (XP56; Mettler Toledo Ltd., Port Melbourne, VIC, Australia). Temperature measurements, on the other hand, were carried out using a handheld thermal camera (Trotec EC060V; Emona Instruments, Pty. Ltd., Melbourne, VIC, Australia).

Example 4

### Method and Characterisation of HKUST-1 [Copper(II)-benzene-1,3,5-tricarboxylate] MOFs

As detailed herein, the acoustically-driven microfluidic platform comprises a piezoelectric substrate (lithium niobate; LiNbO₃), is schematically shown in FIG. 1(a). The pair of interdigital transducers (IDTs) are deliberately patterned off-centre on the substrate in order to break the symmetry of the opposing surface acoustic waves (SAWs)—nanometer-amplitude MHz order electromechanical Rayleigh waves (longitudinal, transversely-polarized, i.e., out-of-plane, surface-propagating compressional waves)—generated upon application of an oscillating electric field at resonance. The transmission of these asymmetrically opposing waves into a 10 μl sessile liquid drop placed atop the substrate then results in an internal microcentrifugal flow 24-28 that has been previously demonstrated for driving extremely efficient micromixing and particle concentration. Subjecting a drop containing 5 μl of a copper precursor and 5 μl of trimesic acid (benzene-1,3,5-tricarboxylic acid; H₃BTC), both in 1:1 (vol/vol) ethanol-water solutions, to such acoustically-driven microcentrifugation at varying acoustic intensities (1.5, 4.5, 7.5 and 9 Vrms) for 5 mins can be seen to induce nucleation and subsequent crystallisation of HKUST-1 crystals (FIG. 2).

Production of stable HKUST-1 MOFs was confirmed with the Fourier Transform Infrared (FTIR) spectra which demonstrated characteristic asymmetric stretching of the carboxylate groups in the H₃BTC molecules at 1508-1623 cm⁻¹ and the symmetric stretching of the carboxylate groups at 1384 and 1405 cm⁻¹. Over wavenumbers 1300-600 cm⁻¹, several bands are observed, which can be attributed to the out-of-plane vibrations of the H₃BTC molecules. Noting the thermal stability of solid HKUST-1 to exceed 300° C., thermal gravimetric analysis (TGA) of one of the samples (9 Vrms), on the other hand, indicated two major stages in the weight loss behaviour of the HKUST-1 crystals, consistent with that observed for bulk HKUST-1.

The orientation of the resultant crystals indicates a strong dependence on the magnitude of the acoustic energy coupled into the drop, which is accompanied by an intensification of the convective microcentrifugation flow. Scanning electron microscopy (SEM) images indicate that increasing the flow intensity results in octahedral crystals typical of HKUST-1 that are progressively smaller and more homogeneous in size. It is observed that the turbulent mixing eddies generated in the flow then results in enhanced convective transport, which is known to lead to the formation of smaller crystals, given that the eddy size imposes an upper limitation to the crystal dimension during its growth.

Significantly, the x-ray diffraction (XRD) spectra of the HKUST-1 crystals synthesized from the methods described exhibit a high degree of orientation parallel to the {222} plane, especially at high input voltages. This is in stark contrast to the control experiment (FIG. 1(b)) in which the crystals that form under slow solvent evaporation of the same drop on identical substrates in the absence of the acoustic forcing show no apparent orientational preference. Interestingly, an increase in the input voltage was observed to lead to more prominent vertical, out-of-plane orientation, as can be seen by the appearance of additional peaks parallel to the {222} plane, such as the {333}, {444} and {555} planes at 2θ=11.7°, 17.7°, 23.7°, and 29.7°, respectively.

SAW excitation along the substrate results in oscillations in the MOF crystalline structure, which, in turn, squeezes the solvents out of the pores, leading to their simultaneous activation, as observed by the colour change in the crystals from a light (solvent-rich) to dark (solvent-poor) blue shade under increasing acoustic field intensities (FIG. 1(c) and FIG. 4(b)).

### Example 5

### Method and Characterisation of Fe-MIL-88B MOFs

In another example, the methods described herein may be used for the preparation of Fe-MIL-88B MOFs, whose working solution was prepared by separately dispersing its precursors, i.e., 31.9 mg iron(III) chloride hexahydrate (FeCl₃.6H₂O; Alfa Aesar GmbH & Co KG, Lancashire, United Kingdom) and 19.1 mg 1,4-benzenedicarboxylic acid (C₆H₄(CO₂H)₂; Sigma Aldrich Pty. Ltd., Castle-Hill, NSW, Australia), in 2.5 ml dimethylformamide (Thermofisher Scientific, Waltham, Mass., USA).

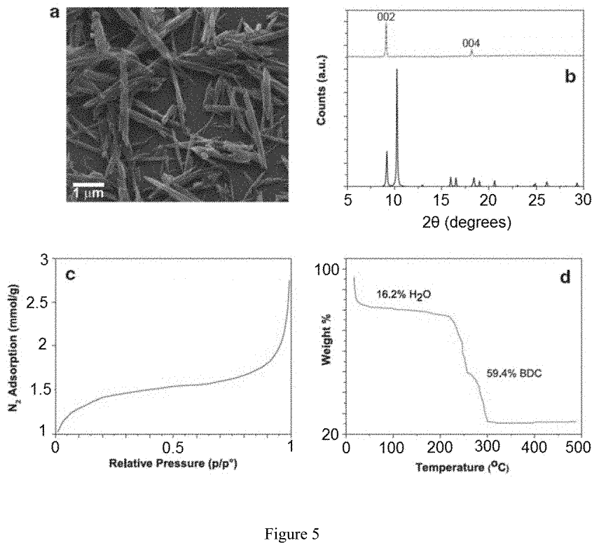

FIG. 5 details characterization of the morphology, orientation, surface area and thermal profile of the synthesized Fe-MIL-88B MOFs. Specifically, FIG. 5 (a) represents a scanning helium ion microscope image, (b) represents powder XRD pattern of the sample (top) against simulated XRD pattern (bottom) obtained from CCDC 1485530, (c) represents N₂ sorption isotherm of MIL-88B (having surface area of 6.0291 m²/g) and, (d) represents thermal gravimetric analysis (TGA) curves for Fe-MIL-88B MOFs at an input voltages of 9 Vrms.

Throughout this specification and the claims which follow, unless the context requires otherwise, the word “comprise”, and variations such as “comprises” and “comprising”, will be understood to imply the inclusion of a stated integer or step or group of integers or steps but not the exclusion of any other integer or step or group of integers or steps.

The reference in this specification to any prior publication (or information derived from it), or to any matter which is known, is not, and should not be taken as an acknowledgment or admission or any form of suggestion that that prior publication (or information derived from it) or known matter forms part of the common general knowledge in the field of endeavour to which this specification relates.

What is claimed is:

1. A method of preparing a Metal Organic Framework (MOF) with an acoustically-driven microfluidic platform, the method comprising:
depositing a liquid comprising MOF precursors on a piezoelectric substrate of an acoustic microfluidic platform, the MOF precursors comprising a metal ion and an organic ligand,
applying acoustic irradiation to the liquid to induce azimuthal liquid recirculation, which causes formation of the MOF within the liquid, and
isolating the MOF.

2. A method according to claim 1 wherein the MOF is at least a partially activated MOF.

3. A method according to claim 1 wherein the MOF is an activated MOF.

4. A method according to claim 1 wherein the MOF has a high degree of orientation.

5. A method according to claim 1 wherein the acoustic irradiation comprises surface acoustic waves, bulk acoustic waves or hybrid acoustic waves comprising both surface and bulk acoustic waves.

6. A method according to claim 4 wherein the surface acoustic waves are Rayleigh surface acoustic waves or shear-horizontal surface acoustic waves.

7. A method according to claim 1 wherein the acoustic irradiation comprises travelling or standing acoustic waves.

8. A method according to claim 1 wherein the azimuthal liquid recirculation is induced by off-centre acoustic waves.

9. A method according to claim 8 wherein the acoustic platform comprises at least one interdigitated transducer (IDT) positioned off-centred relative to the liquid comprising MOF precursors to generate off-centre acoustic waves.

10. A method according to claim 7 wherein the acoustic platform comprises two opposing off-centred IDTs to generate off-centre acoustic waves.

11. A method according to claim 1 wherein the piezoelectric substrate comprises a single crystal substrate.

12. A method according to claim 1 wherein the piezoelectric substrate comprises lithium tantalate or lithium niobate.

13. A method according to claim 1 wherein the acoustic irradiation is generated by applying an input voltage to the piezoelectric substrate, the input voltage being less than 40 Vrms, preferably less than less than 30 Vrms, preferably less than 20 Vrms, preferably less than 10 Vrms, preferably less than 9 Vrms, preferably less than 7.5 Vrms, preferably less than 4.5 Vrms, preferably less than 1.5 Vrms.

14. A method according to claim 1 wherein the method is conducted at a temperature below about 50° C., preferably below about 40° C., more preferably below about 30° C. more preferably below about 25° C., more preferably below about 20° C.

15. A method according to claim 1 wherein the metal ion derives from a metal precursor selected from copper(II) nitrate and iron(III) chloride.

16. A method according to claim 1 wherein the organic ligand derives form an organic linker precursor selected from trimesic acid and 1,4-benzenedicarboxylic acid (BDC).

17. A method according to claim 1 wherein the MOF comprises a surface anchored MOF (SURMOF).

18. A method according to claim 1 wherein the MOF is in the form of a free-standing oriented film.

19. A method according to claim 1 wherein the MOF is in the form of a free-flowing powder.

20. A method according to claim 1 wherein the metal organic framework is HKUST-1 (copper(II)-benzene-1,3,5-tricarboxylate).

21. A method according to claim 1 wherein the MOF is Fe-MIL-88B.

22. A MOF prepared by the method of claim 1.

23. An acoustically-driven microfluidic device for preparation of a Metal Organic Framework (MOF), the device comprising:
a piezoelectric substrate comprising a working surface for accommodating a liquid comprising MOF precursors, the MOF precursors comprising a metal ion and an organic ligand,
at least one interdigitated transducer (IDT) positioned off-centre relative to the working surface,
such that, when the device is in use, off-centred acoustic irradiation generated by the at least one IDTs induces azimuthal recirculation in the liquid comprising MOF precursors, which causes formation of the MOF within the liquid.

24. A device according to claim 23 comprising two opposing off-centred IDTs in opposing directions.

25. A device according to claim 23 wherein the MOF comprises activated MOF.

26. A device according to claim 23 wherein the piezoelectric substrate comprises a single crystal substrate.

27. A device according to claim 23 wherein the piezoelectric substrate comprises lithium tantalate or lithium niobate.

28. A device according to claim 23, being designed to generate the off-centred acoustic irradiation upon application of an input voltage of less than 40 Vrms, preferably less than less than 30 Vrms, preferably less than 20 Vrms, preferably less than 10 Vrms, preferably less than 9 Vrms, preferably less than 7.5 Vrms, preferably less than 4.5 Vrms, preferably less than 1.5 Vrms.

29. A device according to claim 23 wherein the device is operable at a temperature below about 50° C., preferably below about 40° C., more preferably below about 30° C. more preferably below about 25° C., more preferably below about 20° C.
